(19) United States
(12) Patent Application Publication
(10) Pub. No.: US 2008/0179644 A1
(43) Pub. Date: Jul. 31, 2008

(54) CMOS image sensor with drive transistor having asymmetry junction region

(76) Inventors: Hyuck-In Kwon, Seoul (KR); Jung-Chak Ahn, Yongin-Si (KR); Yi-Tae Kim, Hwaseong-Si (KR); Keun-Chan Yuk, Seoul (KR)

Correspondence Address: LAW OFFICE OF MONICA H CHOI, P O BOX 3424, DUBLIN, OH, 430160204, US

(21) Appl. No.: 12/012,049

(22) Filed: Jan. 31, 2008

(30) Foreign Application Priority Data
Jan. 31, 2007 (KR) 2007-10062

(51) Int. Cl. H01L 27/146

(52) U.S. Cl. 257/292; 257/E27.133

(57) ABSTRACT

An image sensor includes a photosensitive device and a drive transistor for generating an electrical signal from charge accumulated in the photosensitive device. The drive transistor includes a source region of a first conductivity type and an asymmetry junction region abutting a portion of the source region and being of a second conductivity type that is opposite of the first conductivity type. The drive transistor is biased such that the asymmetry junction region reduces an effective channel length of the drive transistor.

### BACKGROUND OF THE INVENTION

This application claims priority under 35 USC §119 to Korean Patent Application No. 2007-10062, filed on Jan. 31, 2007 in the Korean Intellectual Property Office, the disclosure of which is incorporated herein in its entirety by reference.

### FIELD OF THE INVENTION

The present invention relates generally to image sensors, and more particularly, to a CMOS (complementary metal oxide semiconductor) image sensor having a drive transistor with an asymmetry junction region for minimizing flicker noise.

### BACKGROUND OF THE INVENTION

An image sensor is a semiconductor device which converts an optical image into electrical signals. An image sensor may be a charge coupled device (CCD) or a CMOS (Complementary Metal Oxide Semiconductor) image sensor (CIS). A unit pixel of a CMOS image sensor includes a photo sensitive device (PSD) to accumulate charge from an image. In addition, the unit pixel includes transistors, such as a transfer transistor, a reset transistor, and a drive transistor, for converting the accumulated charge into an electrical signal for a signal processing circuit.

However, the CMOS image sensor having such a structure may have flicker noise due to charge trapping in an interface between silicon (Si) and silicon oxide (SiO₂), especially in a drive transistor of a unit pixel of the CMOS image sensor. Such flicker noise degrades the quality of the reproduced image. Accordingly, a CMOS image sensor with minimized flicker noise is desired.

### SUMMARY OF THE INVENTION

Accordingly a drive transistor of the CMOS image sensor is formed with an asymmetry junction region for minimizing flicker noise in the CMOS image sensor.

An image sensor according to an aspect of the present invention includes a photosensitive device and a drive transistor for generating an electrical signal from charge accumulated in the photosensitive device. The drive transistor includes a source region of a first conductivity type and an asymmetry junction region abutting a portion of the source region and being of a second conductivity type that is opposite of the first conductivity type.

In one embodiment of the present invention, the first conductivity type is N-type and the second conductivity type is P-type.

In another embodiment of the present invention, the drive transistor further includes a drain region of the first conductivity type and includes a gate dielectric and a gate electrode disposed over a channel region of a semiconductor substrate. The channel region is disposed between the drain and source regions.

In a further embodiment of the present invention, the source region is biased such that an effective channel length of the channel region is increased by the asymmetry junction region. For example, the source region is coupled to a reset voltage supply.

In another embodiment of the present invention, the asymmetry junction region is formed at a bottom corner of the source region to face the channel region of the drive transistor.

In a further embodiment of the present invention, the image sensor further includes a floating diffusion region, a transfer transistor, and a reset transistor. The floating diffusion region is coupled to the gate electrode of the drive transistor. The transfer transistor is coupled between the photosensitive device and the floating diffusion region. The floating diffusion region receives the charge accumulated at the photosensitive device via the transfer transistor. The reset transistor is coupled between the floating diffusion region and the reset voltage supply.

In a method for fabricating an image sensor, a first dopant of the first conductivity type is implanted substantially perpendicular to the semiconductor substrate to form the drain and source regions in the semiconductor substrate at sides of the gate electrode for the drive transistor. A second dopant of the second conductivity type is implanted with a tilt angle for forming the asymmetry junction region abutting the portion of the source region.

The present invention may be used to particular advantage when the image sensor is a CMOS (complementary metal oxide semiconductor) image sensor.

By lengthening the effective channel length of the drive transistor, the asymmetry junction region minimizes flicker noise in the drive transistor and thus in the CMOS image sensor.

### BRIEF DESCRIPTION OF THE DRAWINGS

The above and other features and advantages of the present invention will become more apparent when described in detailed exemplary embodiments thereof with reference to the attached drawings in which:

FIG. 1 is a circuit diagram of a unit pixel included in a CMOS image sensor, according to an embodiment of the present invention;

FIG. 2 shows a layout of the unit pixel of FIG. 1, according to an embodiment of the present invention;

FIG. 3 shows a cross-sectional view of the unit pixel of FIGS. 1 and 2 taken along the line III-III of FIG. 2, according to an embodiment of the present invention; and

FIGS. 4, 5, 6, 7, 8, and 9 are sequential cross-sectional views during fabricating the unit pixel of FIG. 3, according to embodiments of the present invention.

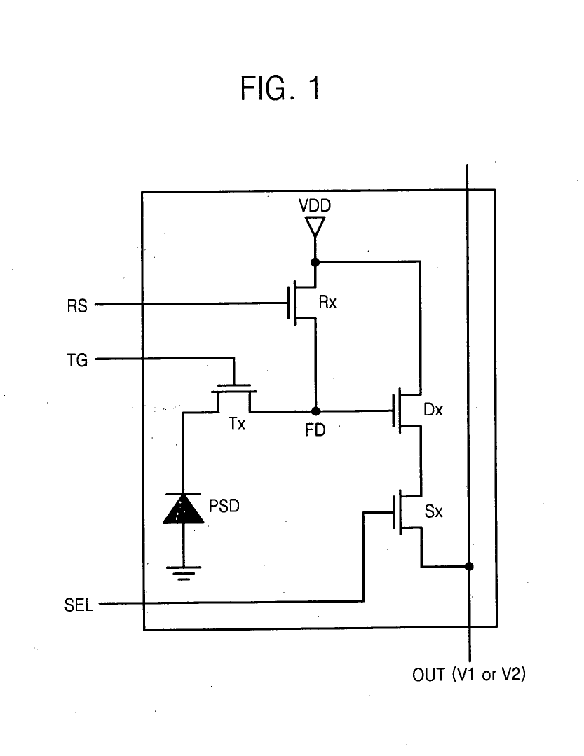

The figures referred to herein are drawn for clarity of illustration and are not necessarily drawn to scale. Elements having the same reference number in FIGS. 1, 2, 3, 4, 5, 6, 7, 8, and 9 refer to elements having similar structure and/or function.

### DETAILED DESCRIPTION OF THE INVENTION

The present invention is now described more fully hereinafter with reference to the accompanying drawings, in which embodiments of the invention are shown. This invention may, however, be embodied in many different forms and should not be construed as limited to the embodiments set forth herein. Rather, these embodiments are provided so that this disclosure will be thorough and complete, and will fully convey the scope of the invention to those skilled in the art. In the drawings, the size and relative sizes of layers and regions may be exaggerated for clarity. Like numbers refer to like elements throughout.

It will be understood that when an element is referred to as being “connected” or “coupled” to another element, it can be directly connected or coupled to the other element or intervening elements may be present. In contrast, when an element is referred to as being “directly connected” or “directly coupled” to another element, there are no intervening elements present. As used herein, the term “and/or” includes any and all combinations of one or more of the associated listed items and may be abbreviated as “/”.

It will be understood that, although the terms first, second, etc. may be used herein to describe various elements, these elements should not be limited by these terms. These terms are only used to distinguish one element from another. For example, a first signal could be termed a second signal, and similarly, a second signal could be termed a first signal without departing from the teachings of the disclosure.

The terminology used herein is for the purpose of describing particular embodiments only and is not intended to be limiting of the invention. As used herein, the singular forms “a”, “an”, and “the” are intended to include the plural forms as well, unless the context clearly indicates otherwise. It will be further understood that the terms “comprises” and/or “comprising,” or “includes” and/or “including” when used in this specification, specify the presence of stated features, regions, integers, steps, operations, elements, and/or components, but do not preclude the presence or addition of one or more other features, regions, integers, steps, operations, elements, components, and/or groups thereof.

Unless otherwise defined, all terms (including technical and scientific terms) used herein have the same meaning as commonly understood by one of ordinary skill in the art to which this invention belongs. It will be further understood that terms, such as those defined in commonly used dictionaries, should be interpreted as having a meaning that is consistent with their meaning in the context of the relevant art and/or the present application, and will not be interpreted in an idealized or overly formal sense unless expressly so defined herein.

FIG. 1 is a circuit diagram of a unit pixel included in a CMOS (complementary metal oxide semiconductor) image sensor, according to an embodiment of the present invention. As illustrated in FIG. 1, the unit pixel includes a photosensitive device (PSD) that generates charge from incident light. The PSD may be implemented by a photo diode, a photo transistor, a photo gate, a pinned photo diode (PPD) or a combination thereof.

In addition in FIG. 1, the unit pixel also includes a transfer transistor Tx, a reset transistor Rx, a drive transistor Dx, and a select transistor Sx. The transfer transistor Tx transfers charge generated by the PSD to a floating diffusion region FD. The reset transistor Rx periodically resets the potential at the floating diffusion region FD to a voltage of a reset voltage supply VDD. The drive transistor Dx is configured as a source follower buffer amplifier for generating an-electrical signal corresponding to the charge stored in the floating diffusion region FD. The select transistor Sx performs switching when the unit pixel of FIG. 1 is selected for signal generation. In FIG. 1, “RS” refers to a control signal applied to a gate of the reset transistor Rx, and “TG” refers to a control signal applied to a gate of the transfer transistor Tx.

The unit pixel of FIG. 1 includes a single PSD and four MOS transistors Tx, Rx, Dx, and Sx, but the present invention is not restricted thereto. The present invention may be practiced with any unit pixel having at least three transistors including a transfer transistor Tx and a source follower buffer amplifier Dx in a transistor region and a PSD.

The operation of the unit pixel of FIG. 1 is now described. The reset transistor Rx, the transfer transistor Tx, and the select transistor Sx are turned on for resetting the unit pixel. In addition, the PSD is depleted, and charge accumulates at the floating diffusion region FD in proportion to a voltage at the reset voltage supply VDD.

Thereafter, the transfer transistor Tx is turned off, and the select transistor Sx is turned on, and then the reset transistor Rx is turned off. A first output voltage V₁ (i.e., a reset signal) is read from an output terminal OUT of the unit pixel and stored in a buffer. Meanwhile, the PSD has been accumulating charge in proportion to an intensity of received light. Thereafter, the transfer transistor Tx is turned on so that the charge accumulated at the PSD is transferred to the floating diffusion region FD. Next, a second output voltage V₂ (i.e., an image signal) is read from the output terminal OUT. For correlated double sampling, analog data corresponding to a difference between the reset and image signals (V₁-V₂) is converted into digital data, thus completing an operating cycle of the unit pixel.

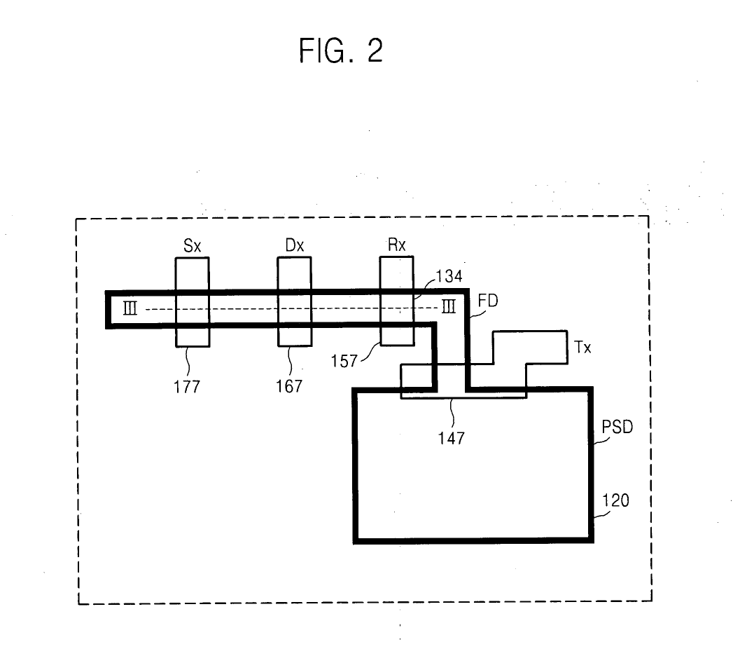

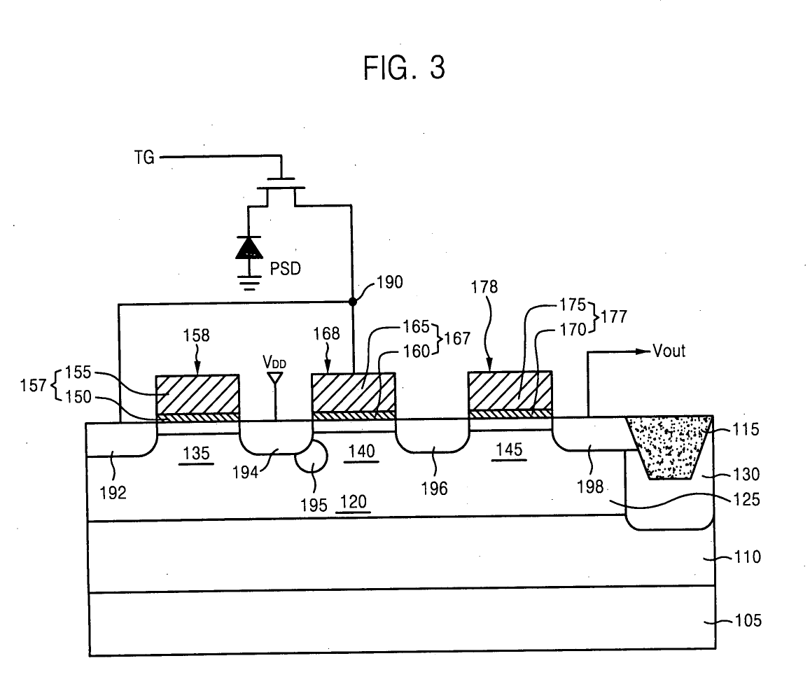

Such CMOS image sensor will be described in more detail with reference to FIGS. 2 and 3. FIG. 2 illustrates a layout of the unit pixel of FIG. 1 according to an example embodiment of the present invention. FIG. 3 is a cross-sectional view of the unit pixel taken along the line III-III of FIG. 2.

Referring to FIG. 2, the unit pixel includes an active region 120 (defined by a bold solid line in FIG. 2) and a device isolation region (115 in FIG. 3) that is outside the active region 120. A gate 147 of the transfer transistor Tx, a gate 157 of the reset transistor Rx, a gate 167 of the drive transistor Dx, and a gate 177 of the select transistor Sx are disposed crossing over the active region 120.

FIG. 3 illustrates a cross-sectional view for the reset transistor Rx 158, the drive transistor Dx 168, and the select transistor Sx 178, as formed in a semiconductor substrate 105. For example, the reset transistor 158, the drive transistor 168, and the select transistor 178 are NMOSFETs (N-channel metal oxide semiconductor field effect transistors) in one embodiment of the present invention.

As illustrated in FIG. 3, a deep P-type well 110 forming a deep conductive path is disposed below the active region 120 in the semiconductor substrate 105 according to one embodiment of the present invention. The semiconductor substrate 105 is a silicon substrate in one embodiment of the present invention. A P-type well 125 doped with P-type impurity ions from a P-type dopant such as boron (B) or boron fluoride (BF₂) for example is disposed on the deep P-type well 110.

In addition, a device isolation region 115 disposed in the P-type well 125 defines the active region 120. The device isolation region 115 is formed using a shallow trench isolation (STI) process or a localized oxidation of silicon (LOCOS) process in one embodiment of the present invention. The device isolation region 115 is surrounded by a channel stop region 130 in one embodiment of the present invention. The channel stop region 130 is a P-type impurity doped region and is in contact with the deep P-type well 110 in one embodiment of the present invention.

A reset gate 157 of the reset transistor 158, a drive gate 167 of the drive transistor 168, and a select gate 177 of the select transistor 178 are disposed on the active region 120 of the semiconductor substrate 105. The reset gate 157, the drive gate 167, and the select gate 177 include gate dielectrics 150, 160, and 170, respectively, and gate electrodes 155, 165, and 175, respectively.

The gate dielectrics 150, 160, and 170 are comprised of a same material such as silicon oxide or silicon nitride for example in one embodiment of the present invention. Similarly, the gate electrodes 155, 165, and 175 are comprised of a same material such as polysilicon, tungsten (W), titanium nitride (TiN), tantalum (Ta), tantalum nitride (TaN), or a combination thereof, in one embodiment of the present invention.

Source/drain regions 192, 194,196, and 198 are formed in the active region 120 of the semiconductor substrate 105 to the sides of the reset gate 157, the drive gate 167, and the select gate 177 as illustrated in FIG. 3. The region 194 forms a drain region of the reset transistor 158 and is coupled to the reset voltage supply VDD. The region 192 forms a source region of the reset transistor 158 and is coupled to a floating node 190 which is the floating diffusion region FD.

The drive transistor 168 shares the drain region 194 with the reset transistor 158 and shares the source region 196 with the select transistor 178. For example, the drain region 194 of the reset transistor 158 corresponds to the source region 194 of the drive transistor 168, and the source region 196 of the select transistor 178 corresponds to the drain region 196 of the drive transistor 168. The drain region 198 of the select transistor 178 is coupled to the output node OUT that generates an output voltage VOUT. The source/drain regions 192, 194, 196, and 198 are doped with an N-type dopant in one embodiment of the present invention. The designation of each of the regions 192, 194, 196, and 198 as a source or drain region for each of the transistors 158, 168, and 178 is by way of example only and may be interchanged.

Channel regions 135, 140, and 145 are formed under the gates 157, 167, and 177, respectively, for the transistors 158, 168, and 178, respectively. In addition, the channel region 135 is disposed between the source/drain regions 192 and 194, the channel region 140 is disposed between the source/drain regions 194 and 196, and the channel region 145 is disposed between the source/drain regions 196 and 198.

Impurity ions are implanted into such channel regions 135, 140, and 145 for controlling threshold voltages of the reset transistor 158, the drive transistor 168, and the select transistor 178, respectively. For example, a P-type dopant is implanted into the channel regions 135, 140, and 145 in one embodiment of the present invention. Additionally, an N-type dopant may also be implanted below a P-type doped layer in the channel regions 135,140, and 145 for forming a stack structure of multiple doped layers therein.

According to an aspect of the present invention, a junction region (hereinafter, referred to as an “asymmetry junction region”) 195 is formed to abut a portion of the source region 194 of the drive transistor 168. A P-type dopant such as boron (B) is used for doping the asymmetry junction region 196. According to an example embodiment of the present invention, the source region 194 of the drive transistor 168 has a first conductivity type such as N-type conductivity, and the asymmetry junction region 196 has a second conductivity type such a P-type conductivity that is opposite to the first conductivity type of the source region 194.

In one embodiment of the present invention, the asymmetry junction region 195 has a pocket shape protruding from a portion of a bottom corner of the source region 194 of the drive transistor 168 toward the channel region 140 of the drive transistor 168. The source region 194 of the drive transistor 168 has the voltage of the reset voltage supply VDD applied thereon. Such as voltage of the reset voltage supply VDD tends to be a relatively high voltage. Thus, the source region 194 has higher potential than the drain region 196 of the drive transistor 168 such that the strength of an electric field near the drain region 196 of the drive transistor 168 is minimized.

The drive transistor 168 having the asymmetry junction region 195 advantageously has reduced flicker noise from two effects. First, since the strength of the electric field near the drain region 196 of the drive transistor 168 is reduced into the channel region 140, the length of a pinch-off region is reduced such that an effective channel length is increased. Since the amount of flicker noise is in inverse proportion to the effective channel length, the increase of the effective channel length minimizes the flicker noise.

In addition, as an electric field increases in the source region 194 of the driver transistor 168 with the asymmetry junction region 195 nearby, an average carrier velocity also increases in the channel region 140. Generally, a bottleneck of carrier mobility in a channel region is near a source region with a small electric field. With the increased electric field in the source region 194, the average carrier velocity in the channel region 140 is increased such that the amount of required inversion charge for the drive transistor 168 to drive a predetermined amount of current is reduced. Since the flicker noise is in inverse proportion to the amount of inversion charge, the reduced inversion charge results in minimized flicker noise.

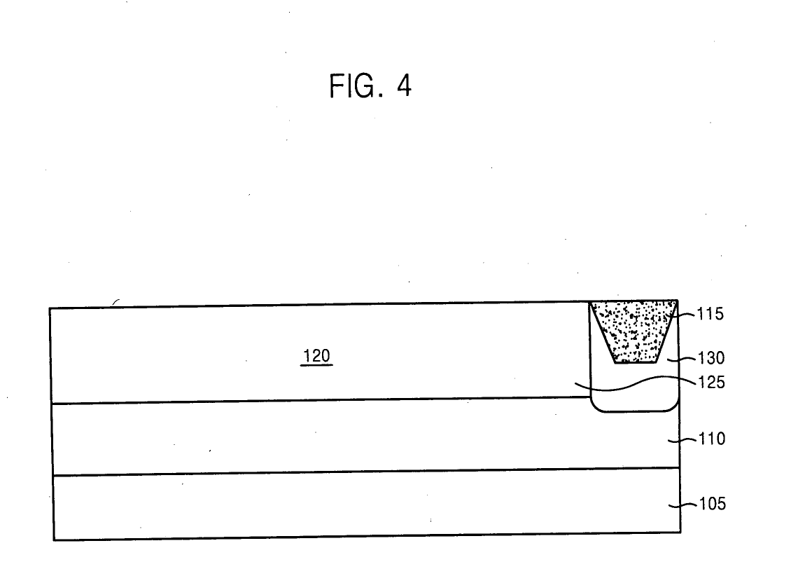

A method of fabricating the unit pixel of FIGS. 1 and 3 according to embodiments of the present invention is now described with reference to FIGS. 4, 5, 6, 7, 8, and 9. FIGS. 4, 5, 6, 7, 8, and 9 show cross-sectional views of the unit pixel during sequential fabrication steps according to embodiments of the present invention.

Referring to FIG. 4, the deep P-type well 110 is formed in the semiconductor substrate 105 comprised of silicon for example. In an example embodiment of the present invention, the deep P-type well 110 is formed by implanting a P-type dopant such as boron (B) or boron fluoride (BF₂) deep into the semiconductor substrate 105.

Thereafter, the device isolation region 115 is formed in the semiconductor substrate 105 using a shallow trench isolation (STI) process or a localized oxidation of silicon (LOCOS) process for example to define the active region 120 in the semiconductor substrate 105. Next, the P-type well 125 is formed in the active region such that NMOSFETs (N-channel metal oxide field effect transistors) may be formed therein. In addition, the channel stop region 130 contacting the deep P-type well 110 is formed below the device isolation region 115 in one embodiment of the present invention. For instance, the channel stop region 130 is formed by implanting a P-type dopant in one embodiment of the present invention.

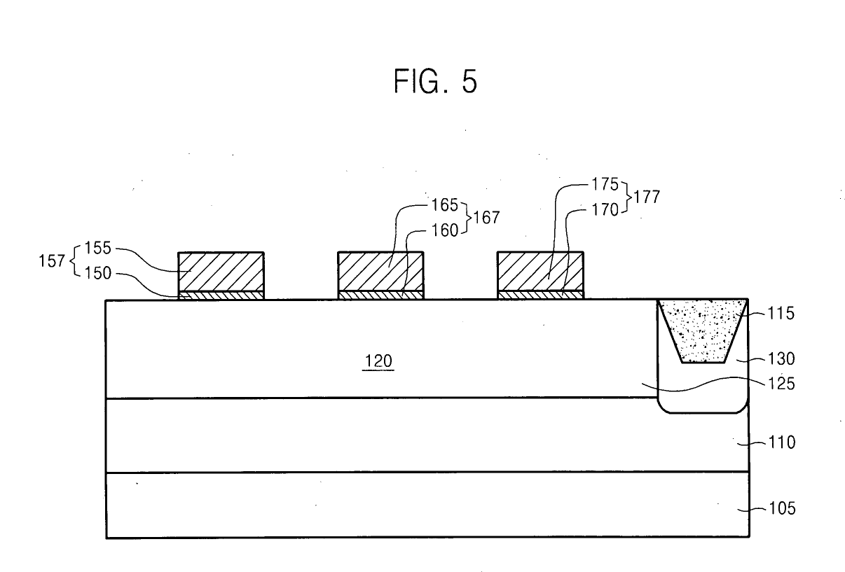

Subsequently referring to FIG. 5, a gate dielectric layer (not shown) and a gate electrode layer (not shown) are sequentially formed on the active region 120 of the semiconductor substrate 105. For example, the gate dielectric layer may be formed using thermal oxidation or may be formed by depositing an oxide or a nitride using chemical vapor-deposition (CVD). The gate electrode layer is comprised of polysilicon, tungsten (W), titanium nitride (TiN), tantalum (Ta), tantalum nitride (TaN), or a combination thereof, in an example embodiment of the present invention.

Thereafter, the reset gate 157, the drive gate 167, and the select gate 177 are patterned using a photolithography process for example from such a gate dielectric layer and such a gate electrode layer. In this manner, the gate dielectrics 150, 160, and 170 are patterned from such a gate dielectric layer for the reset gate 157, the drive gate 167, and the select gate 177, respectively. Similarly, the gate electrodes 155, 165, and 175 are patterned from such a gate electrode layer for the reset gate 157, the drive gate 167, and the select gate 177, respectively.

Although not shown, before the gates 157, 167, and 177 are formed, a P-type dopant may be implanted for forming P⁻-type regions in the channel regions (135, 140, and 145 in FIG. 3) under the gates 157, 167, and 177 for controlling the threshold voltage of the reset, drive, and select transistors (158, 168, and 178 in FIG. 3), respectively. In addition, an N-type dopant may also be implanted below such P⁻-type regions in the channel regions 135, 140, and 145 to form a respective stack structure of an N⁻-type region below the P⁻-type region for each of the channel regions 135, 140, and 145. Here, the order of implanting the P-type dopant and the N-type dopant for forming such P⁻-type regions and N⁻-type regions is not limited to any particular order.

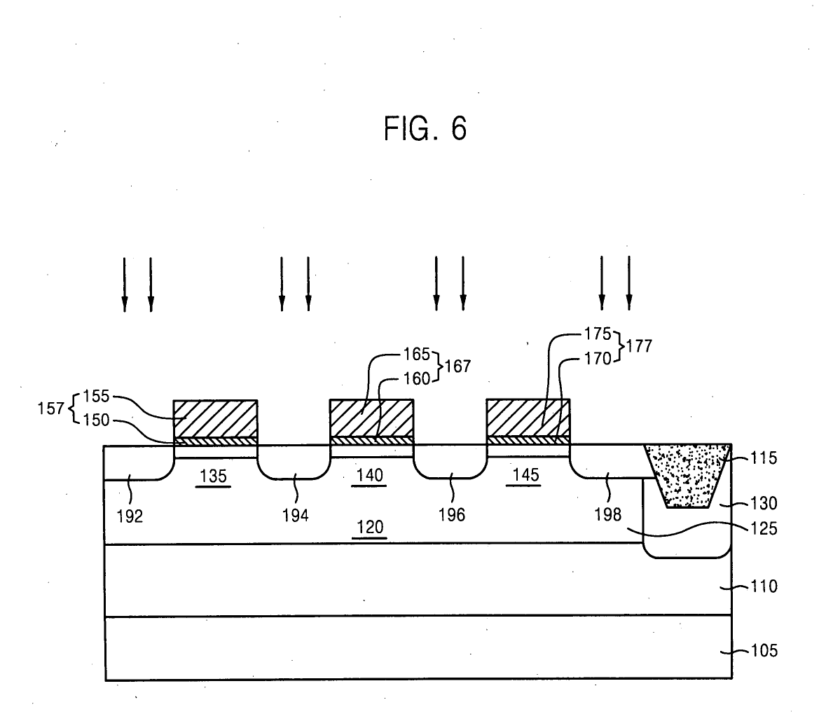

Subsequently referring to FIG. 6, an N-type dopant is implanted substantially perpendicular to the semiconductor substrate 105 to form the source/drain regions 192, 194, 196, and 198 that are substantially N⁺-type junctions formed in the active region 120 between the gates 157, 167, and 177. In that case, the gates 157, 167, and 177 are used as an implantation mask. In an alternative embodiment of the present invention, before the source and drain regions 192, 194, 196, and 198 are formed, gate spacers (not shown) may be formed on sidewalls of the gates 157, 167, and 177. Designation of each of the regions 192, 194, 196, and 198 as a drain or a source is by way of example only and may be interchanged.

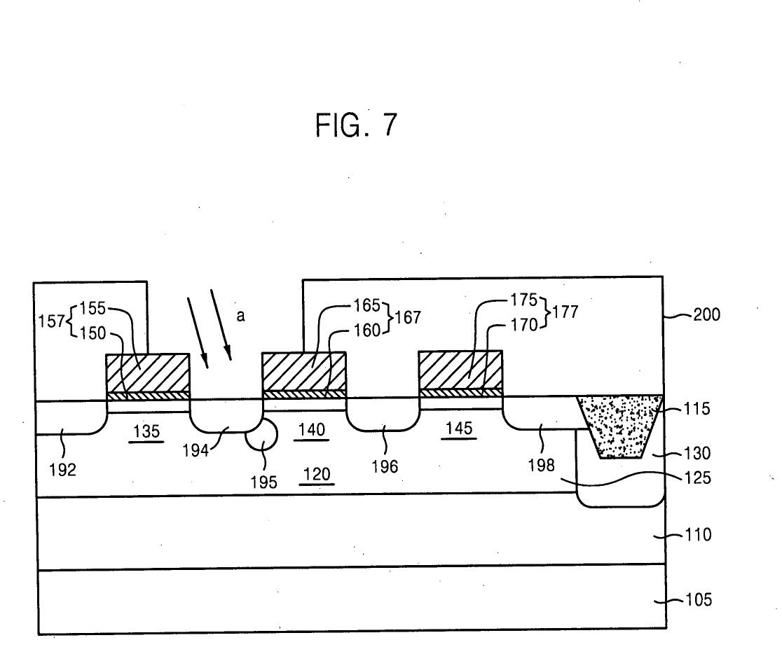

Thereafter referring to FIG. 7, an implantation mask 200 is formed on the semiconductor substrate 105 to expose the source region 194 of the drive transistor 168. In addition, a portion of the reset gate 157 and a portion of the drive gate 167 are also exposed in an example embodiment of the present invention. Subsequently, a P-type dopant such as boron (B) is implanted in an “a” direction with a tilt angle of from about 5 to about 15 degrees with respect to the semiconductor substrate 105 to form the P⁺-type asymmetry junction region 195.

With such a tilt angle of implantation, the asymmetry junction region 195 is formed at a bottom corner of the source region 194 of the drive transistor 168 such that the asymmetry junction region 195 faces the channel region 140 of the drive transistor 168. Thus, the asymmetry junction region 195 abuts a portion of the source region 194 of the drive transistor 168. The remaining portion of the source region 194 abuts the P-type well 125.

Generally, a doped region designated as P⁺-type has a dopant concentration of at least an order of magnitude greater than a region designated as P-type. In addition, a doped region designated as P⁻-type has a dopant concentration of at least an order of magnitude less than a region designated as P-type. Similarly, a doped region designated as N⁺-type has a dopant concentration of at least an order of magnitude greater than a region designated as N-type. In addition, a doped region designated as N⁻-type has a dopant concentration of at least an order of magnitude less than a region designated as N-type.

As described with reference to FIG. 3, the asymmetry junction region 195 increases an effective channel length of the drive transistor 168 and also reduces the amount of required inversion charge in the drive transistor 168. Accordingly, flicker noise is advantageously reduced in the CMOS image sensor having such a drive transistor with the asymmetry junction region 195.

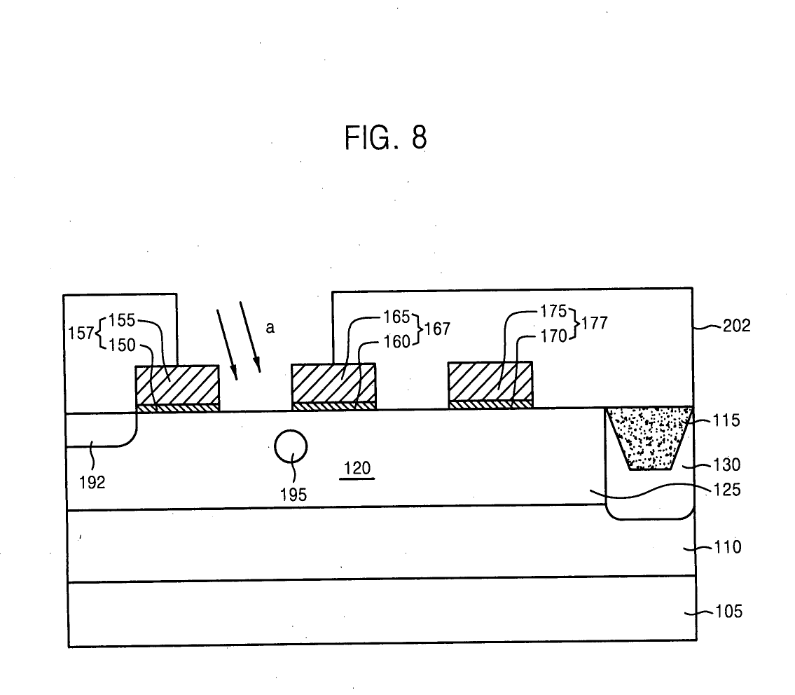

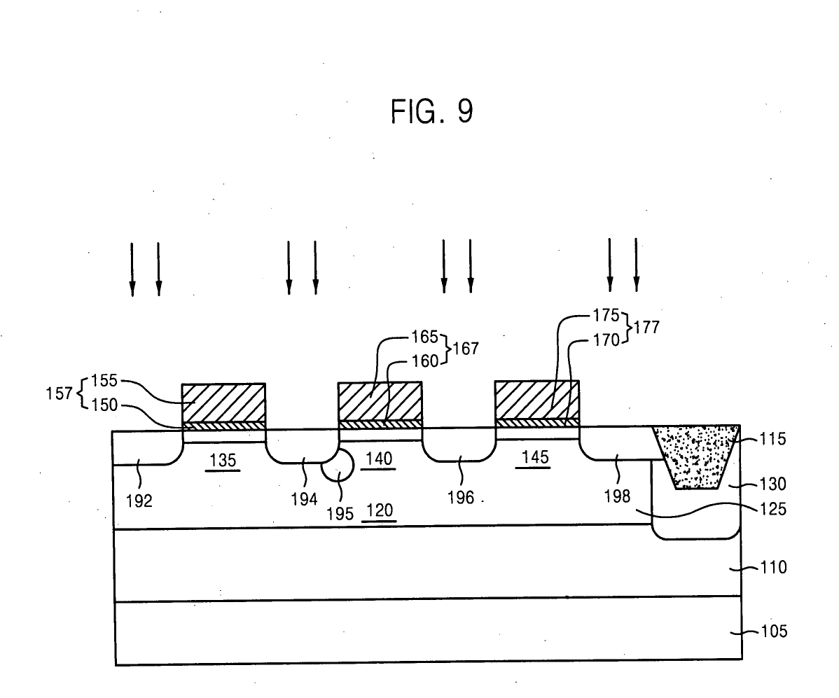

In FIGS. 6 and 7, the asymmetry junction region 195 is formed after the source/drain regions 192, 194, 196, and 198 are formed. The present invention may also be practiced with the asymmetry junction region 195 being formed before the source/drain regions 192, 194, 196, and 198 are formed as illustrated in FIGS. 8 and 9. Referring to FIG. 8, an implantation mask 202 is formed on the semiconductor substrate 105 after the reset gate 157, the drive gate 167, and the select gate 177 are formed and before the source/drain regions 192, 194, 196, and 198 are formed.

Further in FIG. 8, the P-type dopant is then implanted with the tilt angle to form the asymmetry junction region 195. Thereafter referring to FIG. 9, the implantation mask 202 is removed, and the N-type dopant is implanted substantially perpendicular with respect to the semiconductor substrate 105 using the gates 157, 167, and 177 as an implantation mask to form the N⁺-type source/drain regions 192, 194, 196, and 198. Thereafter, light receiving lenses (not shown) and metal wiring (not shown) are formed using typical CMOS fabrication methods know to those skilled in the art, thereby completing the CMOS image sensor.

While the present invention has been shown and described with reference to exemplary embodiments thereof, it will be understood by those of ordinary skill in the art that various changes in form and detail may be made herein without departing from the spirit and scope of the present invention, as defined by the following claims.

The present invention is limited only as defined in the following claims and equivalents thereof.

What is claimed is:

1. An image sensor comprising:
a photosensitive device; and
a drive transistor for generating an electrical signal from charge accumulated in the photosensitive device, the drive transistor including:
a source region of a first conductivity type; and
an asymmetry junction region abutting a portion of the source region and being of a second conductivity type that is opposite of the first conductivity type.

2. The image sensor of claim 1, wherein the first conductivity type is N-type and the second conductivity type is P-type.

3. The image sensor of claim 1, wherein the drive transistor further includes:
a drain region of the first conductivity type;
a gate dielectric and a gate electrode disposed over a channel region of a semiconductor substrate, the channel region being disposed between the drain and source regions.

4. The image sensor of claim 3, wherein the source region is biased such that an effective channel length of the channel region is increased by the asymmetry junction region.

5. The image sensor of claim 4, wherein the source region is coupled to a reset voltage supply.

6. The image sensor of claim 3, wherein the asymmetry junction region is formed at a bottom corner of the source region to face the channel region of the drive transistor.

7. The image sensor of claim 3, further comprising:
a floating diffusion region coupled to the gate electrode of the drive transistor.

8. The image sensor of claim 7, further comprising:
a transfer transistor coupled between the photosensitive device and the floating diffusion region;
wherein the floating diffusion region receives the charge accumulated at the photosensitive device via the transfer transistor.

9. The image sensor of claim 8, further comprising:
a reset transistor coupled between the floating diffusion region and a reset voltage supply;
wherein the source region of the drive transistor is coupled to the reset voltage supply.

10. The image sensor of claim 1, wherein the image sensor is a CMOS (complementary metal oxide semiconductor) image sensor.

11. An image sensor comprising:
a photosensitive device; and
a drive transistor for generating an electrical signal from charge accumulated in the photosensitive device, the drive transistor including:
a source region of a first conductivity type; and
means for increasing a channel region of the drive transistor using an asymmetry junction region abutting a portion of the source region.

12. The image sensor of claim 11, wherein the first conductivity type is N-type and the second conductivity type is P-type.

13. The image sensor of claim 11, wherein the drive transistor further includes:
a drain region of the first conductivity type;
a gate dielectric and a gate electrode disposed over the channel region of a semiconductor substrate, the channel region being disposed between the drain and source regions.

14. The image sensor of claim 13, wherein the source region is biased such that an effective channel length of the channel region is increased by the asymmetry junction region.

15. The image sensor of claim 14, wherein the source region is coupled to a reset voltage supply.

16. The image sensor of claim 13, wherein the asymmetry junction region is formed at a bottom corner of the source region to face the channel region of the drive transistor.

17. The image sensor of claim 13, further comprising:
a floating diffusion region coupled to the gate electrode of the drive transistor.

18. The image sensor of claim 17, further comprising:
a transfer transistor coupled between the photosensitive device and the floating diffusion region;
wherein the floating diffusion region receives the charge accumulated at the photosensitive device via the transfer transistor.

19. The image sensor of claim 18, further comprising:
a reset transistor coupled between the floating diffusion region and a reset voltage supply;
wherein the source region of the drive transistor is coupled to the reset voltage supply.

20. The image sensor of claim 11, wherein the image sensor is a CMOS (complementary metal oxide semiconductor) image sensor.
